(19) United States
(12) Patent Application Publication
(10) Pub. No.: US 2023/0178326 A1
(43) Pub. Date: Jun. 8, 2023

(54) CHARGED PARTICLE BEAM GENERATION

(71) Applicant: Microchip Technology Incorporated, Chandler, AZ (US)

(72) Inventors: Hyunwook Park, Burlington, MA (US); Nakri Dao, Lynn, MA (US); Kim Richard Overstreet, Danvers, MA (US)

(21) Appl. No.: 18/061,338

(22) Filed: Dec. 2, 2022

Related U.S. Application Data
(60) Provisional application No. 63/264,922, filed on Dec. 3, 2021.

(51) Int. Cl. H01J 37/147; H01J 37/24

(52) U.S. Cl. CPC H01J 37/147; H01J 37/242; H01J 37/243; H01J 2237/24535; H01J 2237/24585

(57) ABSTRACT

One or more examples relate, generally, to an apparatus. The apparatus includes a charged particle source and a charged particle pointer. The charged particle pointer urges charged particles emitted by the charged particle source in a predetermined direction. The charged particle pointer comprises a repeller, and an isolator positioned along a path extending from the repeller in the predetermined direction.

### CROSS-REFERENCE TO RELATED APPLICATIONS

This application claims the benefit of the priority date of U.S. Provisional Patent Application No. 63/264,922, filed Dec. 3, 2021, and titled “COMPACT CHARGED-PARTICLE BEAM GENERATOR,” the disclosure of which is incorporated herein in its entirety by this reference.

### FIELD

One or more examples relate, generally, to charged particle beam generation, and more specifically, to a charged particle beam generator. Example charged particle generator may be utilized without, or with, an accelerator or ion lens.

### BACKGROUND

Charged particle beam generators are used to transfer charged particles in a predetermined direction, such as toward a target or region of interest, in a generally precise manner.

### BRIEF DESCRIPTION OF THE DRAWINGS

To easily identify the discussion of any particular element or act, the most significant digit or digits in a reference number refer to the figure number in which that element is first introduced.

FIG. 1A is a schematic diagram depicting a perspective view of an apparatus to generate a charged particle beam, in accordance with one or more examples.

FIG. 1B is a schematic diagram depicting a side view of apparatus of FIG. 1A, in accordance with one or more examples.

FIG. 2 is a schematic diagram that depicts a system generating an example charged particle beam via an apparatus of FIG. 1A and FIG. 1B, in accordance with one or more examples.

FIG. 3 is a block diagram depicting a control circuit to control generation of a charged particle beam utilizing a charged particle beam generation apparatus of FIG. 1A and FIG. 1B, in accordance with one or more examples.

FIG. 4 is a flow diagram depicting a process to control generation of a charged particle beam utilizing a charged particle beam generation apparatus, in accordance with one or more examples.

FIG. 5 is a block diagram depicting a system to generate a charged particle beam, in accordance with one or more examples.

FIG. 6 is a block diagram of circuit that, in some examples, may be used to implement various functions, operations, acts, processes, or methods disclosed herein.

### DETAILED DESCRIPTION

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, any relational term, such as “over,” “under,” “on,” “underlying,” “upper,” “lower,” etc., is used for clarity and convenience in understanding the disclosure and accompanying drawings and does not connote or depend on any specific preference, orientation, or order, except where the context clearly indicates otherwise.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

In this description the term “coupled” and derivatives thereof may be used to indicate that two elements cooperate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The terms “on” and “connected” may be used in this description interchangeably with the term “coupled,” and have the same meaning unless expressly indicated otherwise or the context would indicate otherwise to a person having ordinary skill in the art.

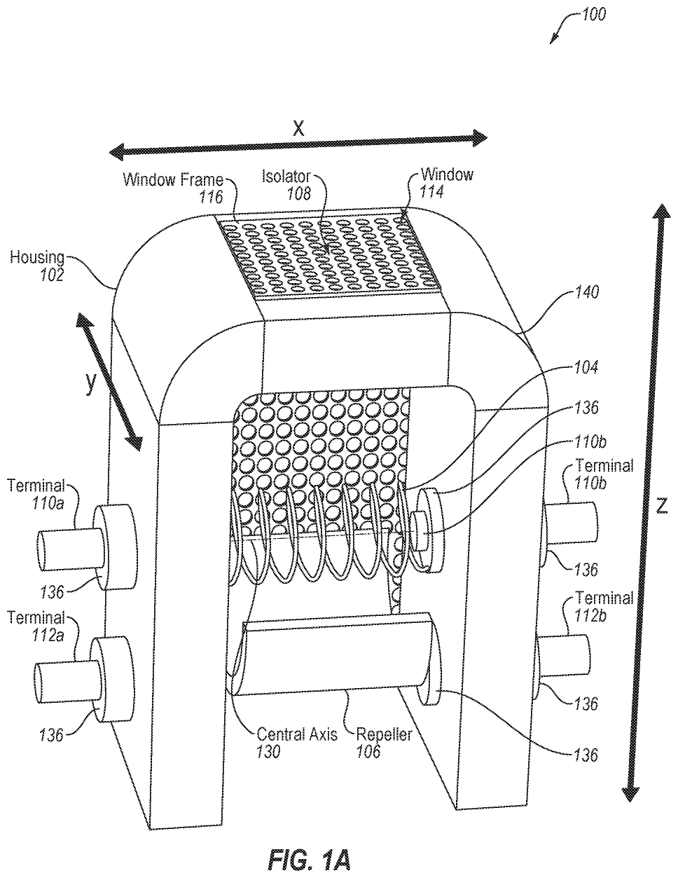

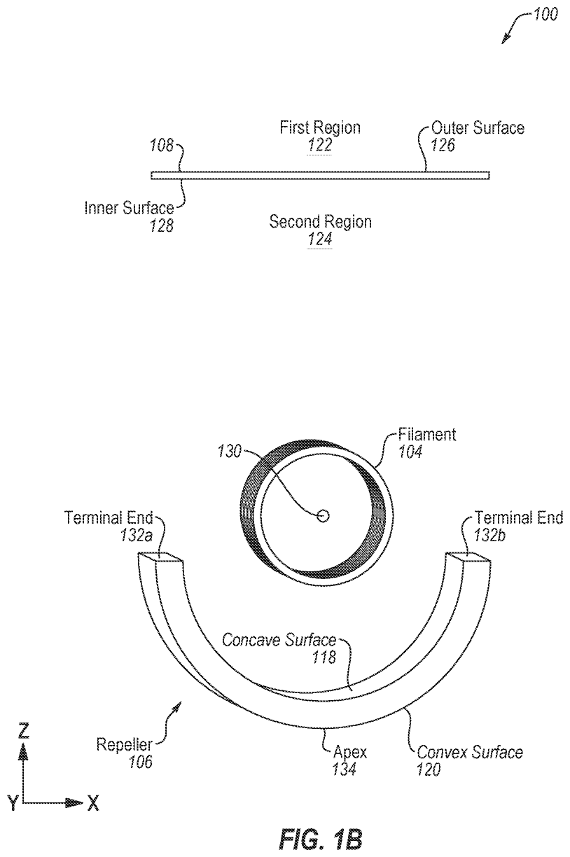

FIG. 1A is a schematic diagram depicting a perspective view of a charged particle beam generation apparatus 100 to generate a charged particle beam, in accordance with one or more examples. FIG. 1B is a schematic diagram depicting a side view of charged particle beam generation apparatus 100, in accordance with one or more examples. Charged particle beam generation apparatus 100 may also be referred to herein as charged particle beam generation apparatus 100.

In one or more examples, charged particle beam generation apparatus 100 generates a charged particle beam by directing charged particles generated therein. Charged particle beam generation apparatus 100 includes a filament 104 and a repeller 106 disposed within a housing 102, and further includes an isolator 108 located in or at a wall of housing 102.

Housing 102 may comprise one or more reference members attached to each other, or to a support, in the arrangement depicted by FIG. 1A. A material of housing 102, and reference members thereof may be a conductive material (e.g., metal or conductive ceramic, without limitation). A material of housing 102, and reference members thereof may further be, as non-limiting examples, a non-magnetic material (e.g., negligibly magnetic material, without limitation), a weakly magnetic material, a magnetic material, or a combination or sub-combination thereof.

Filament 104 generates charged particles for an electron beam. In one or more examples, filament 104 is a hot-cathode, as in the specific example depicted by FIG. 1A and FIG. 1B, that is directly heated. A temperature of filament 104 increases in response to an electrical current flowing there through. Filament 104 is arranged in housing 102 between a first pair of terminals 110a/110b. Terminals 110a/110b are located at, and extend through, respective opposing walls of housing 102. When respective ends of filament 104 are coupled to respective ones of terminals 110a/110b, the terminals 110a/110b provide a conductive path from an electrical power source (not shown), which may be a current source, located external to housing 102 to filament 104. The temperature of filament 104 may be set (e.g., set by a temperature control circuit, without limitation) via a magnitude of a current provided by the electrical power source (e.g., provided by a current source and set by a current control circuit, without limitation).

When an electrical current flows through terminal 110a, filament 104, and terminal 110b, the temperature of filament 104 increases and the heated filament 104 emits charged particles (e.g., ions or electrons, without limitation) via thermionic emission. In one or more examples, a material of filament 104 may be any material or composite that can reliably stimulate emission of a predictable number of charged particles per unit time as a function of temperature (e.g., per second, without limitation), such as tungsten, without limitation. In one or more examples, filament 104 may be a single structure (e.g., a single tungsten coil, without limitation) or different structures (e.g., a heating wire deposed within a hollow tungsten walled tube, without limitation). A quantity of charged particles emitted by filament 104 or rate of emission of charged particles by filament 104 may be set (e.g., set by a charged particle emission rate control circuit, without limitation) via the temperature of filament 104 (e.g., set by a temperature control circuit as discussed above, without limitation).

An electrical insulator material 136 may be provided as an electrical barrier between terminals 110a/110b and 112a/112b and a conductive material of housing 102. Housing 102 includes a terminal 140 to apply a voltage potential to housing 102, as a non-limiting example, a ground voltage potential or other voltage potential.

Isolator 108 is formed of a conductive material, which isolator 108 is transparent to a charged particle beam (as discussed below), to electrically isolate a first region 122 adjacent an outer surface 126 of the isolator 108, with respect to housing 102, as depicted by FIG. 1B, without limitation, from a second region 124 adjacent an inner surface 128 of isolator 108, the inner surface 128 opposite the outer surface 126, with respect to housing 102, as depicted by FIG. 1B, without limitation.

In one or more examples, isolator 108 may be sized and shaped to fit in window 114 defined in a front wall of housing 102. Window frame 116 supports isolator 108 in the window 114. In one or more examples, alternatively to being positioned in window 114, isolator 108 may be sized and shaped to at least cover window 114 when positioned over or under window 114. In one or more examples, isolator 108 may be formed or machined from a conductive material of the front wall of housing 102.

In one or more examples, isolator 108 is electrically coupled to housing 102, directly or indirectly (e.g., via window frame 116, without limitation).

In one or more examples, isolator 108 allows charged particles to exit housing 102 and substantially blocks electric fields generated inside housing 102. In the specific non-limiting example depicted by FIG. 1A, isolator 108 comprises lines or strips of overlapping conductive material in a grid-like arrangement to form a generally flat mesh sheet. In one or more examples, the mesh of the isolator 108 is a mesh structure that is substantially transparent to a charged particle beam, where the transparency is selected based on operating conditions. In one or more examples, the mesh of isolator 108 is 90% transparent to a charged particle beam (e.g., 90% of the surface area is empty space, without limitation). In one or more examples, a material of isolator 108 is or more of copper, silver, aluminum, or gold. A region adjacent the inner surface 128 of isolator 108 may be an interior region of the charged particle beam generation apparatus 100, i.e., second region 124, and a region adjacent the first surface of the isolator 108 may be an exterior region to the charged particle beam generation apparatus 100, i.e., first region 122. In one or more examples, isolator 108 may be permanently or removably attached to housing 102. In one or more examples, isolator 108 may be formed or machined from a conductive material of the front wall of housing 102 (e.g., holes, slits, or the like of may be formed or machined into a conductive material of front wall of housing 102, without limitation, to define isolator 108).

Repeller 106 energizes and collimates an electron beam, and more specifically, an electron beam of charged particles emitted by filament 104. Repeller 106 may be formed of a conductive material sized and shaped so that a body of repeller 106 extends parallel to a central axis 130 of filament 104 (i.e., central axis 130 is the axis that filament 104 appears to wind around in FIG. 1A, substantially the x-direction in FIG. 1) and portions of repeller 106 are at different vertical distances (in the z-direction in FIGS. 1A-1B) from isolator 108. In the specific example depicted by FIG. 1A, repeller 106 exhibits a parabolic shaped cross-section in the y-z plane and the body of repeller 106 extends in the x-direction. Repeller 106 is arranged in housing 102 between a second pair of terminals 112a/112b, which provide a conductive path from a voltage source (not depicted) to repeller 106.

When voltage potentials are respectively applied to isolator 108 and repeller 106 such that a positive voltage potential is present between repeller 106 and isolator 108 (i.e., a voltage level exhibited at isolator 108 is higher than a voltage level exhibited by repeller 106), isolator 108 and repeller 106 function as a “pointer” that urges charged particles emitted by filament 104 in a predetermined direction, specifically, toward isolator 108. The voltage difference field due to the voltage potential difference between isolator 108 and repeller 106 generates an electric field normal to the concave surface of repeller 106 (which may be modeled as multiple electric fields all normal to the surface of repeller 106) with a negative pole at repeller 106 and a positive pole at isolator 108. The electric field urges negatively charged particles (i.e., electronics) emitted by filament 104 toward a positive pole of the electric field (i.e., isolator 108). The concave surface 118 of repeller 106 generally points component electrical fields at the periphery inward in a gradually decreasing angle from the terminal ends 132a/132b to the apex 134 (see FIG. 1B) where the component electrical fields point straight toward the isolator 108. Charged particles propagate along the z-axis and are confined in the x-y plane, forming a column-like beam. The voltage potential at repeller 106 may be set (e.g., set by a voltage control circuit, without limitation) to correspond to an energy amount for a charged particle beam.

A person of ordinary skill in the art would understand that a negative potential between repeller 106 and isolator 108 may be used to with a filament 104 that emits positively charged particles (i.e., protons) in the manner described, above.

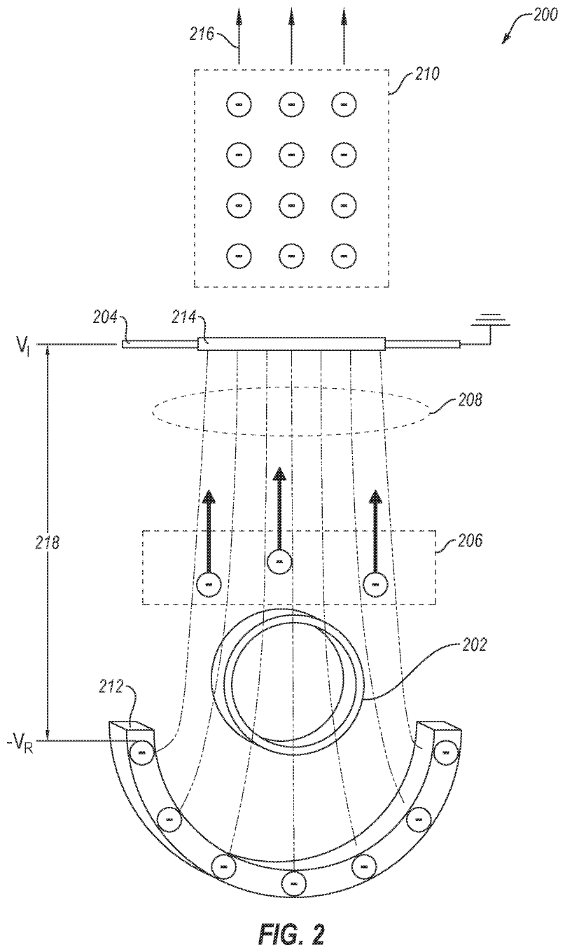

Repeller 106 is not limited to the specific parabolic shape depicted by FIGS. 1A, 1B and 2, and repeller 106 may exhibit other parabolic shapes without exceeding the scope of this disclosure. As a non-limiting example, repeller 106 may be V-shaped where the apex 134 of repeller 106 exhibits a corner or vertex shape as compared to the curved shape depicted by FIGS. 1A, 1B, and 2.

As a non-limiting example, repeller 106 may include multiple flat structures with respective surfaces that are individually oriented such that component electrical fields normal to the respective surfaces point generally as discussed above with respect to parabolic shaped structure.

Suitable distances between repeller 106, filament 104, and isolator 108 may be chosen based on specific operating conditions.

FIG. 2 is a schematic diagram that depicts a system 200 generating a charged particle beam via a charged particle beam generation apparatus 100 of FIG. 1A and FIG. 1B, in accordance with one or more examples. System 200 is a perspective view of an x-y cross-section, analogous to the side view of FIG. 1B, of interior components of charged particle beam generation apparatus 100 during a contemplated operation, for example, charged particle source 202, repeller 212, and isolator 204. Charged particle source 202 is a non-limiting example of filament 104, repeller 212 is a non-limiting example of repeller 106, isolator 204 is a non-limiting example of isolator 108, and window 214 is a non-limiting example of window 114, respectively of FIGS. 1A-1B.

System 200 includes a charged particle pointer 218 and charged particle source 202. Charged particle pointer 218 includes a repeller 212 with a voltage potential −V_{R} and isolator 204 with a voltage potential V_{I}, where the voltage difference from V_{R} to V_{I} is positive, i.e., voltage potential V_{I} is more positive than voltage potential V_{R}. Charged particle source 202 is located between repeller 212 and isolator 204 of charged particle pointer 218. Electric field lines 208 extend from repeller 212 toward isolator 204 (e.g., in a cathode-anode type arrangement where negative voltage potential −V_{R} at repeller 212 is the cathode of the electric field and a positive voltage potential V_{I} (which may be, for example, ground, without limitation) at isolator 204 is the anode of the electric field) and urge (via magnetic forces) the negatively charged particles 206 (i.e., electrons) emitted by charged particle source 202 toward window 214 comprising isolator 204. Electric field lines 208 collimate the negatively charged particles 206 emitted by charged particle source 202 and urge the columnated charged particles 206 toward window 214 and isolator 204. Charged particles 206 that exit via window 214 exhibit an arrangement 210, and more specifically, a collimated beam, and travel in direction 216 (toward the top of the sheet of FIG. 2).

A voltage difference between repeller 212 and isolator 204 (i.e., ΔV=V_{I}−(−V_{R})) is utilized in lieu of an accelerator, ion lens and associated electronics in a typical charged particle beam generator, such as an electron gun. The magnitude of the voltage difference may be chosen based on desired energy of the particle where ΔV=1V creates about 1 eV of energy.

While FIG. 1A, FIG. 1B, and FIG. 2, illustrate a single example of a charged particle beam generation apparatus, the present disclosure is not so limited, and multiple such charged particle beam generation apparatuses may be utilized together, as a non-limiting example, to direct multiple beams of charged particles toward a target.

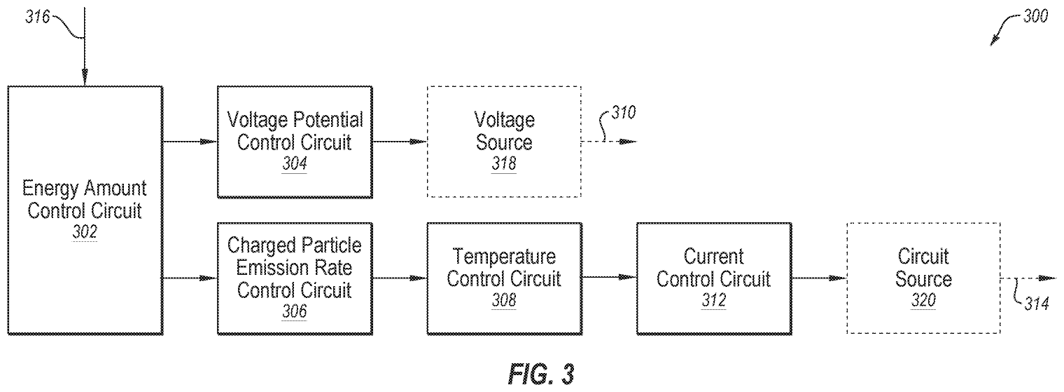

FIG. 3 is a block diagram depicting an apparatus 300 to control generation of a charged particle beam utilizing a charged particle beam generation apparatus 100, in accordance with one or more examples. Apparatus 300 includes an energy amount control circuit 302, a voltage potential control circuit 304, a charged particle emission rate control circuit 306, a temperature control circuit 308, and a current control circuit 312. FIG. 3 also depicts an optional voltage source 318 and an optional current source 320, which, more generally, may be understood to be electrical power sources. In examples where apparatus 300 does not include optional voltage source 318 and optional current source 320, apparatus 300 may be understood to be a “control circuit 300.” In examples where apparatus 300 includes optional voltage source 318, optional current source 320, or both, apparatus 300 may be understood to be an “electrical power generation apparatus 300.”

Control circuit 300 controls electric power sources, such as optional voltage source 318 and optional current source 320, to generate a voltage for a repeller (e.g., repeller 106 of FIGS. 1A and 1B or repeller 212 of FIG. 2, without limitation) and a current for a charged particle source (e.g., filament 104 of FIGS. 1A and 1B or charged particle source 202 of FIG. 2, without limitation).

Energy amount control circuit 302 determines, at least partially responsive to a target energy amount 316 to be delivered by charged particle beam generation apparatus 100, a voltage potential of repeller 106 in relation to a voltage potential of isolator 108, and a charged particle emission rate of filament 104. Target energy amount 316 is a value that represents an amount of energy to be delivered via a charged particle beam generated by charged particle beam generation apparatus 100. The determined charged particle emission rate of filament 104 is a value that represents a rate at which charged particles are to be emitted by a charged particle source (e.g., by filament 104 or charged particle source 202). The determined voltage potential of repeller 106 is a value that represents a voltage potential to be applied to repeller 106 to achieve a voltage difference between respective voltage potentials of isolator 108 and repeller 106 suitable to urge charged particles emitted by a charged particle source toward window 114 and isolator 108. Energy amount control circuit 302 generates a command to generate the determined voltage potential at repeller 106, and a command to emit charged particles by filament 104 at the determined charged particle emission rate.

Voltage potential control circuit 304 determines a voltage at least partially responsive to the voltage potential commanded by energy amount control circuit 302. The determined voltage is a value the represents a voltage to apply to repeller 106 to achieve the voltage potential commanded by energy amount control circuit 302. Voltage potential control circuit 304 generates a command to generate the determined voltage. Optional voltage source 318 generates a voltage 310 at least partially responsive to the voltage commanded by voltage potential control circuit 304. A voltage 310 generated by optional voltage source 318 may be applied to repeller 106 via terminals 112a or 112b.

Charged particle emission rate control circuit 306 determines a temperature of filament 104 at least partially responsive the charged particle emission rate commanded by energy amount control circuit 302. The determined temperature is a value that represents a temperature of filament 104 to cause charged particle emission at the charged particle emission rate commanded by energy amount control circuit 302. Charged particle emission rate control circuit 306 generates a command to heat filament 104 to the determined temperature.

Temperature control circuit 308, determines a current at least partially responsive to the temperature commanded by charged particle emission rate control circuit 306. The determined current is a value that represents a magnitude of electrical current flow through filament 104 suitable to achieve the temperature commanded by the charged particle emission rate control circuit 306. Temperature control circuit 308 generates a command for optional current source 320 to generate the determined current. In one or more examples, temperature control circuit 308 may adjust the determined current and generate further commands for optional current source 320 at least partially responsive to a sensed temperature of a filament 104 to maintain the temperature of filament 104 at the determined temperature.

Current control circuit 312 determines a current at least partially responsive to the current commanded by temperature control circuit 308. The determined current is a value that represents a current to apply to filament 104 via terminals 110a or 110b to achieve the current commanded by temperature control circuit 308. Current control circuit 312 generates a command to generate the determined current. Optional current source 320 may generate a current 314 at least partially responsive to the current commanded by current control circuit 312. The current 314 generated by optional current source 320 for application to filament 104 via terminals 110a or 110b.

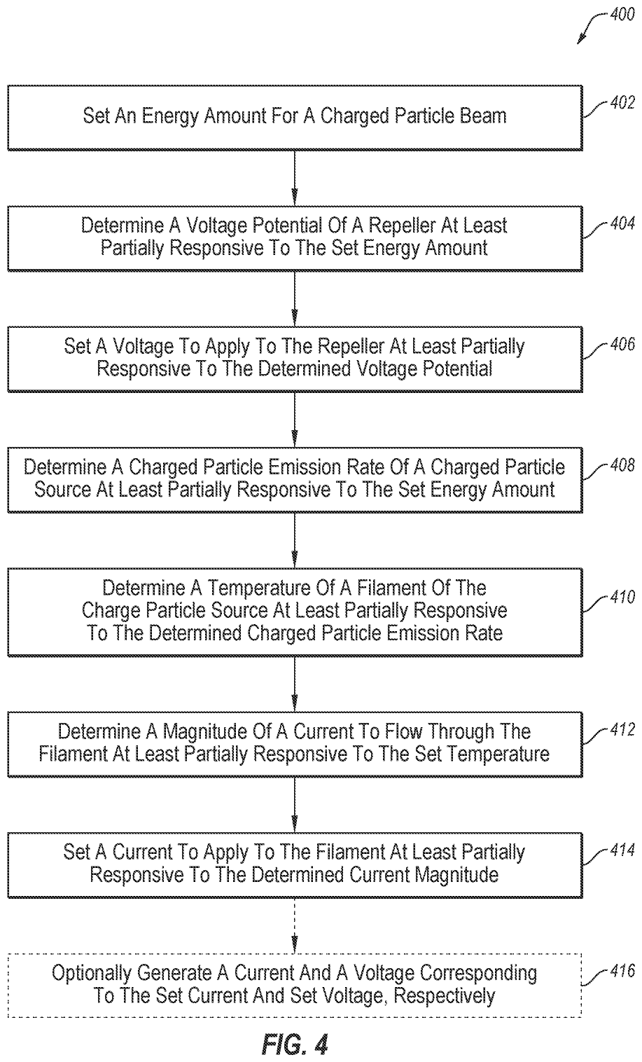

FIG. 4 is a flow diagram depicting a process 400 to control generation of a charged particle beam utilizing a charged particle beam generation apparatus 100, in accordance with one or more examples. Process 400 may be performed, as a non-limiting example, by a control circuit 300.

Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence.

One or more operations of process 400 may be performed, as a non-limiting example, by one or more control circuits, including a current control circuit, temperature control circuit, and/or charged particle emission rate control circuit, without limitation.

At operation 402, process 400 sets an energy amount for a charged particle beam at operation 402.

At operation 404, process 400 determines a voltage potential of a repeller at least partially responsive to the set energy amount.

At operation 406, process 400 sets a voltage to apply to the repeller at least partially responsive to the determined voltage potential.

At operation 408, process 400 determines a charged particle emission rate of a charged particle source at least partially responsive to the set energy amount.

At operation 410, process 400 determines a temperature of a filament of the charge particle source at least partially responsive to the determined charged particle emission rate.

At operation 412, process 400 determines a magnitude of a current to flow through the filament at least partially responsive to the set temperature.

At operation 414, process 400 sets a current to apply to the filament at least partially responsive to the determined current magnitude.

At optional operation 416, process 400 generates a current and a voltage corresponding to the set current and set voltage, respectively.

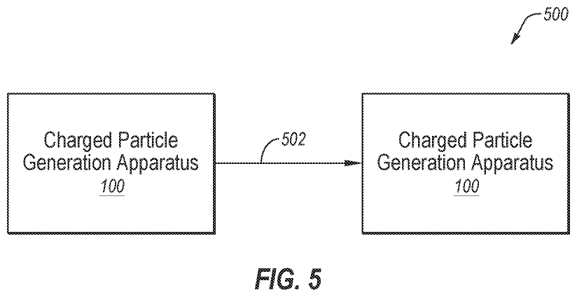

FIG. 5 is a block diagram depicting a system 500 to generate a charged particle beam, in accordance with one or more examples.

System 500 includes an electrical power generation apparatus 300 and charged particle beam generation apparatus 100. Charged particle beam generation apparatus 100 and electrical power generation apparatus 300 are coupled so that charged particle beam generation apparatus 100 may generate charged particle beams responsive to control signals 502 (e.g., current control 314 and voltage control 310, without limitation) generated by control circuit 300.

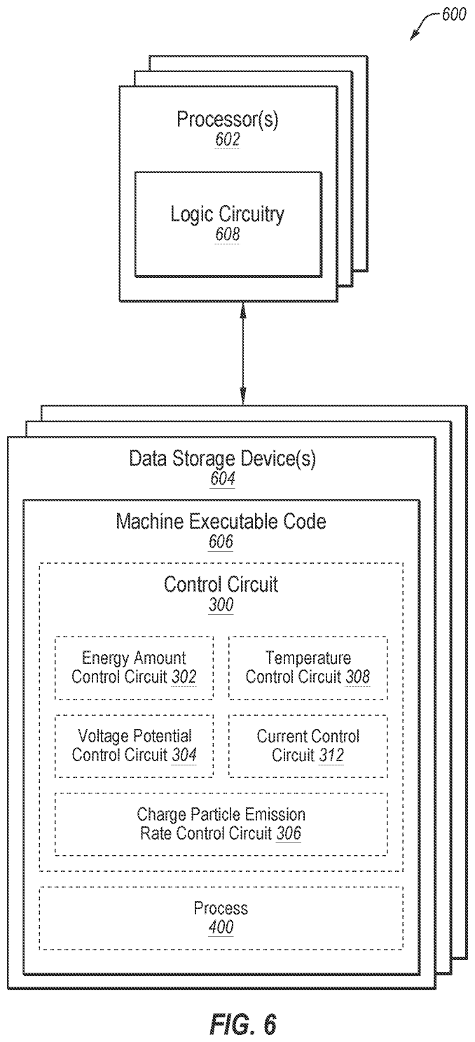

It will be appreciated by those of ordinary skill in the art that functional elements of examples disclosed herein (e.g., functions, operations, acts, processes, or methods) may be implemented in any suitable hardware, software, firmware, or combinations thereof. FIG. 6 illustrates non-limiting examples of implementations of functional elements disclosed herein. In some examples, some or all portions of the functional elements disclosed herein may be performed by hardware specially configured for carrying out the functional elements.

FIG. 6 is a block diagram of a circuit 600 that, in some examples, may be used to implement various functions, operations, acts, processes, or methods disclosed herein. The circuit 600 includes one or more processors 602 (sometimes referred to herein as “processors 602”) operably coupled to one or more data storage devices 604 (sometimes referred to herein as “storage 604”). The storage 604 includes machine-executable code 606 stored thereon and the processors 602 include logic circuit 608. The machine-executable code 606 information describing functional elements that may be implemented by (e.g., performed by) the logic circuit 608. The logic circuit 608 implements (e.g., performs) the functional elements described by the machine-executable code 606. The circuit 600, when executing the functional elements described by the machine-executable code 606, should be considered as special purpose hardware configured for carrying out functional elements disclosed herein. In some examples the processors 602 may perform the functional elements described by the machine-executable code 606 sequentially, concurrently (e.g., on one or more different hardware platforms), or in one or more parallel process streams.

When implemented by logic circuit 608 of the processors 602, the machine-executable code 606 adapts the processors 602 to perform operations of examples disclosed herein. By way of non-limiting example, the machine-executable code 606 may be adapt the processors 602 to perform some or a totality of operations of one or more of process 400 of FIG. 4.

Also by way of non-limiting example, the machine-executable code 606 may adapt the processors 602 to perform some or a totality of features, functions, or operations disclosed herein for one or more of control circuit 300 and system 500. More specifically, features, functions, or operations disclosed herein for one or more of energy amount control circuit 302, voltage potential control circuit 304, charged particle emission rate control circuit 306, temperature control circuit 308, and current control circuit 312.

The processors 602 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device, discrete gate or transistor logic, discrete hardware components, other programmable device, or any combination thereof designed to perform the functions disclosed herein. A general-purpose computer including a processor is considered a special-purpose computer while the general-purpose computer is configured to execute functional elements corresponding to the machine-executable code 606 (e.g., software code, firmware code, hardware descriptions) related to examples of the present disclosure. It is noted that a general-purpose processor (may also be referred to herein as a host processor or simply a host) may be a microprocessor, but in the alternative, the processors 602 may include any conventional processor, controller, microcontroller, or state machine. The processors 602 may also be implemented as a combination of computing devices, such as a combination of a DSP and a microprocessor, a plurality of microprocessors, one or more microprocessors in conjunction with a DSP core, or any other such configuration.

In some examples, the storage 604 includes volatile data storage (e.g., random-access memory (RAM)), non-volatile data storage (e.g., Flash memory, a hard disc drive, a solid state drive, erasable programmable read-only memory (EPROM), without limitation). In some examples the processors 602 and the storage 604 may be implemented into a single device (e.g., a semiconductor device product, a system on chip (SOC), without limitation). In some examples, the processors 602 may and the storage 604 may be implemented into separate devices.

In some examples the machine-executable code 606 may include computer-readable instructions (e.g., software code, firmware code). By way of non-limiting example, the computer-readable instructions may be stored by the storage 604, accessed directly by the processors 602 may, and executed by the processors 602 may using at least the logic circuit 608. Also by way of non-limiting example, the computer-readable instructions may be stored on the storage 604, transferred to a memory device (not shown) for execution, and executed by the processors 602 using at least the logic circuit 608. Accordingly, in some examples the logic circuit 608 includes electrically configurable logic circuit 608.

In some examples the machine-executable code 606 may describe hardware (e.g., circuitry) to be implemented in the logic circuit 608 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, SystemVerilog or very large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 608 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine-executable code 606 may include an HDL, an RTL, a GL description, a mask level description, other hardware description, or any combination thereof.

In examples where the machine-executable code 606 includes a hardware description (at any level of abstraction), a system (not shown, but including the storage 604) may be configured to implement the hardware description described by the machine-executable code 606. By way of non-limiting example, the processors 602 may include a programmable logic device (e.g., an FPGA or a PLC) and the logic circuit 608 may be electrically controlled to implement circuitry corresponding to the hardware description into the logic circuit 608. Also by way of non-limiting example, the logic circuit 608 may include hard-wired logic manufactured by a manufacturing system (not shown, but including the storage 604) according to the hardware description of the machine-executable code 606.

Regardless of whether the machine-executable code 606 includes computer-readable instructions or a hardware description, the logic circuit 608 is adapted to perform the functional elements described by the machine-executable code 606 when implementing the functional elements of the machine-executable code 606. It is noted that although a hardware description may not directly describe functional elements, a hardware description indirectly describes functional elements that the hardware elements described by the hardware description are capable of performing.

A person having ordinary skill in the art will appreciate many applications for disclosed examples of charged particle beam generators, as a non-limiting example, in an atomic clock to ionize atoms.

A person having ordinary skill in the art would appreciate many benefits and advantages of examples, as a non-limiting example, compact design that facilitates an ionizer in a miniaturized ion clock minimizing disturbance in trapping field; elimination of parts of conventional electron beam generators for example, replaces typical accelerator, ion lens and associated electronics with a voltage difference (e.g., between a repeller and an isolator, without limitation).

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.” As used herein, “each” means some or a totality. As used herein, “each and every” means a totality.

Any characterization in this description of something as “typical,” “conventional,” “known,” or the like does not necessarily mean that it is disclosed in the prior art or that the discussed aspects are appreciated in the prior art. Nor does it necessarily mean that, in the relevant field, it is widely known, well understood, or routinely used. Such characterizations should be understood to mean “known to the inventor(s) of this disclosure.”

Additional non-limiting examples of the disclosure include:

Example 1: An apparatus, comprising: a charged particle source; and a charged particle pointer to collimate and urge charged particles emitted by the charged particle source toward a predetermined direction, the charged particle pointer comprising: a repeller; and an isolator positioned along a path extending from the repeller in the predetermined direction.

Example 2: The apparatus according to Example 1, wherein the isolator to electrically isolate a first region from a second region, the first region adjacent an outer surface of the isolator, and the second region adjacent an inner surface of the isolator.

Example 3: The apparatus according to any of Examples 1 and 2, wherein the isolator comprises a material that is conductive and is transparent to a charged particle beam.

Example 4: The apparatus according to any of Examples 1 through 3, wherein the material is a mesh structure positioned in, on or under a window frame.

Example 5: The apparatus according to any of Examples 1 through 4, wherein charged particle source is located between the repeller and the isolator.

Example 6: The apparatus according to any of Examples 1 through 5, wherein a cross-section of the repeller exhibits a parabolic shape.

Example 7: The apparatus according to any of Examples 1 through 6, wherein a curved surface of the repeller generally points component electrical fields at a periphery of the repeller inward in a gradually decreasing angle from respective terminal ends of the repeller to an apex of the repeller where component electrical fields point generally straight toward the isolator.

Example 8: The apparatus according to any of Examples 1 through 7, wherein the repeller to energize and collimate charged particles into a beam.

Example 9: The apparatus according to any of Examples 1 through 8, comprising a housing with the charged particle source and charged particle pointer disposed within the housing.

Example 10: The apparatus according to any of Examples 1 through 9, wherein the housing includes a first pair of terminals arranged on opposite surfaces of the housing and a second pair of terminals arranged on opposite surfaces of the housing, and wherein the charged particle source is coupled between the first pair of terminals, and wherein the repeller is coupled between the second pair of terminals.

Example 11: A method, comprising: setting an energy amount for a charged particle beam; determining a voltage potential of a repeller at least partially responsive to the set energy amount; setting a voltage to apply to the repeller at least partially responsive to the determined voltage potential; determining a charged particle emission rate of a charged particle source at least partially responsive to the set energy amount; determining a temperature of a filament of the charged particle source at least partially responsive to the determined charged particle emission rate; determining a magnitude of current to flow through the filament at least partially responsive to the determined temperature; and setting a current to apply to the filament of the charged particle source at least partially responsive to the determined magnitude of current.

Example 12: The method according to Example 11, comprising: generating the current and the voltage corresponding to the set current and set voltage, respectively.

Example 13: An apparatus, comprising: at least one processor; and at least one data storage device to store instructions to adapt the at least one processor to: set an energy amount for a charged particle beam; determine a voltage potential of a repeller at least partially responsive to the set energy amount; setting a voltage to apply to the repeller at least partially responsive to the determined voltage potential; determine a charged particle emission rate of a charged particle source at least partially responsive to the set energy amount; determine a temperature of a filament of the charged particle source at least partially responsive to the determined charged particle emission rate; determine a magnitude of current to flow through the filament at least partially responsive to the determined temperature; and set a current to apply to the filament of the charged particle source at least partially responsive to the determined magnitude of current.

What is claimed is:

1. An apparatus, comprising:
a charged particle source; and
a charged particle pointer to collimate and urge charged particles emitted by the charged particle source toward a predetermined direction, the charged particle pointer comprising:
a repeller; and
an isolator positioned along a path extending from the repeller in the predetermined direction.

2. The apparatus of claim 1, wherein the isolator to electrically isolate a first region from a second region, the first region adjacent an outer surface of the isolator, and the second region adjacent an inner surface of the isolator.

3. The apparatus of claim 2, wherein the isolator comprises a material that is conductive and is transparent to a charged particle beam.

4. The apparatus of claim 3, wherein the material is a mesh structure positioned in, on or under a window frame.

5. The apparatus of claim 1, wherein charged particle source is located between the repeller and the isolator.

6. The apparatus of claim 1, wherein a cross-section of the repeller exhibits a parabolic shape.

7. The apparatus of claim 1, wherein a curved surface of the repeller generally points component electrical fields at a periphery of the repeller inward in a gradually decreasing angle from respective terminal ends of the repeller to an apex of the repeller where component electrical fields point generally straight toward the isolator.

8. The apparatus of claim 1, wherein the repeller to energize and collimate charged particles into a beam.

9. The apparatus of claim 1, comprising a housing with the charged particle source and charged particle pointer disposed within the housing.

10. The apparatus of claim 9, wherein the housing includes a first pair of terminals arranged on opposite surfaces of the housing and a second pair of terminals arranged on opposite surfaces of the housing, and wherein the charged particle source is coupled between the first pair of terminals, and wherein the repeller is coupled between the second pair of terminals.

11. A method, comprising:
setting an energy amount for a charged particle beam;
determining a voltage potential of a repeller at least partially responsive to the set energy amount;
setting a voltage to apply to the repeller at least partially responsive to the determined voltage potential;
determining a charged particle emission rate of a charged particle source at least partially responsive to the set energy amount;
determining a temperature of a filament of the charged particle source at least partially responsive to the determined charged particle emission rate;
determining a magnitude of current to flow through the filament at least partially responsive to the determined temperature; and
setting a current to apply to the filament of the charged particle source at least partially responsive to the determined magnitude of current.

12. The method of claim 11, comprising:
generating the current and the voltage corresponding to the set current and set voltage, respectively.

13. An apparatus, comprising:
at least one processor; and
at least one storage device to store instructions to adapt the at least one processor to:
set an energy amount for a charged particle beam;
determine a voltage potential of a repeller at least partially responsive to the set energy amount;
setting a voltage to apply to the repeller at least partially responsive to the determined voltage potential;
determine a charged particle emission rate of a charged particle source at least partially responsive to the set energy amount;
determine a temperature of a filament of the charged particle source at least partially responsive to the determined charged particle emission rate;
determine a magnitude of current to flow through the filament at least partially responsive to the determined temperature; and
set a current to apply to the filament of the charged particle source at least partially responsive to the determined magnitude of current.
